(19) United States
(12) Patent Application Publication
(10) Pub. No.: US 2021/0047489 A1
(43) Pub. Date: Feb. 18, 2021

(54) LAYERED COATING SYSTEM FOR LONG-TERM OUTDOOR EXPOSURE

(71) Applicants: Kettering University, Flint, MI (US); Shin-Etsu Chemical Co., Ltd., Annaka (JP)

(72) Inventors: Mary A. Gilliam, Farmington Hills, MI (US); Susan A. Farhat, Holt, MI (US); Koichi Higuchi, Annaka (JP); Kohei Masuda, Annaka (JP); Ryosuke Yoshii, Annaka (JP)

(21) Appl. No.: 17/041,700

(22) PCT Filed: Mar. 27, 2019
(86) PCT No.: PCT/US2019/024223

§ 371 Date: Sep. 25, 2020

Related U.S. Application Data
(60) Provisional application No. 62/649,111, filed on Mar. 28, 2018.

(51) Int. Cl. C08J 7/04; C08J 7/046; C08K 3/014; C08K 3/22; C08K 5/00; C08K 5/3492; C08K 5/3472; C08K 9/02; C08K 9/10; C23C 16/513; B05D 1/00

(52) U.S. Cl. CPC C08J 7/042; C08K 2201/011; C08K 3/014; C08K 3/22; C08K 5/005; C08K 5/3492; C08K 5/3472; C08K 9/02; C08K 9/10; C23C 16/513; B05D 1/62; C08J 2383/05; C08K 2003/2213; C08K 2003/2241; C08K 2003/2296; C08K 2201/003; C08J 7/046

(57) ABSTRACT

A layered coating system with enhanced properties capable of protecting an article or a component of an article from exposure to outdoor elements, including UV radiation, extreme temperatures, water, acid rain, other fluids and chemicals; scratching and marring from surface contact; and more. The layered coating system and articles formed therewith are characterized by properties that can include UV-absorption, abrasion and scratch resistance, adhesion to the substrate and within the coating layers, haze and visible light transparency, and impact resistance.

### CROSS REFERENCE TO RELATED APPLICATIONS

This application is a 35 U.S.C. § 371 national phase application of International Application No.: PCT/US2019/024223, filed Mar. 27, 2019, which claims the benefit of priority under 35 U.S.C. § 119(e) of U.S. Provisional Application No. 62/649,111 filed on Mar. 28, 2018, the entire contents of which are both incorporated herein by reference in their entirety.

### FIELD

This disclosure relates generally to a layered coating system applied to a plastic substrate that exhibits weatherability and abrasion resistance, as well as articles or components of an article formed therefrom and a method of making the same.

### BACKGROUND

The statements in this section merely provide background information related to the present disclosure and may not constitute prior art.

Coating systems that consist of multiple layers are often applied to plastic components to protect such components from exposure to UV radiation and the environment. Long-term outdoor exposure can limit the life-time of a coated plastic component by causing the component to be scratched or marred, exhibit excessive wear, become hazy, change color, lose transparency, peel, delaminate, or crack, to name a few conditions. Many products, e.g., automobiles, which are routinely exposed to the environment, are lasting longer than previously expected. However, the coated plastic components incorporated into these products often fail before the lifetime of the product.

Often the regulations for coated plastic materials are not up-to-date with the changes encountered in the market relative to product lifetimes. For example, the U.S. Federal Motor Vehicle Safety Standards for automobile headlights require a 3-year outdoor weathering exposure test, while the average lifetime of an automobile has increased to greater than eleven years. Headlamp haze and yellowing from failed coating systems have been linked to pedestrian fatalities due to automobile accidents occurring during the night.

A variety of different coating types may be applied to the external surface of a component in an attempt to improve the lifetime of the component. These coating types include organic coatings, radiation-curable coatings, siloxane-based coating systems with/without a primer, organic UV-absorbing coatings, inorganic UV-reflecting coatings, and plasma-deposited films. However, organic coatings and radiation-cured coatings typically do not achieve sufficient scratch and abrasion resistance for long-term outdoor exposure. Although siloxane-based coatings may offer an increase in scratch and abrasion resistance, the addition of organic UV absorbing molecules to siloxane-based coatings typically decreases their resistance to scratch and abrasion.

Another issue with organic and siloxane-based coatings is the leaching of the UV absorbing molecules out of the coatings overtime under conditions of outdoor exposure, thereby, making the component susceptible to UV degradation. One way to reduce the leaching of the organic UV absorbing molecules is to chemically bond the UV-absorbing functional group to the organic polymer or siloxane precursor that is used to form the coating and/or primer used therewith. Inorganic UV reflecting agents, such as ZnO and TiO₂, may provide more permanent UV protection than organic UV absorbing molecules, which degrade from exposure to ultraviolet radiation (UV).

Plasma Enhanced Chemical Vapor Deposition (PECVD) films may be used to enhance abrasion resistance. A PECVD film may provide sufficient abrasion resistance for the protection of a component during long-term outdoor exposure. However, the application of PECVD films requires the use of vacuum pressure processing, which is very costly due to a high capital cost, operating costs, and significant maintenance and downtime.

### SUMMARY

The present disclosure generally provides a weatherable and abrasion resistant coating system. This coating system comprises two or more coating layers that at least partially encapsulate an organic resin substrate. The coating layers include an outer layer (I) formed of an abrasion resistant atmospheric PECVD film and an inner layer (II) that has a cured composition comprising: (II-A) a silicone resin; (II-B) an UV absorber; and (II-C) optionally, a residual amount of solvent. The silicone resin is a reaction product obtained by (co)hydrolyzing, condensing, or (co)hydrolyzing-condensing a member selected from oxysilanes and partial hydrolytic condensates thereof. The oxysilane generally corresponds to Formula (F-1):

(R¹)ₘ(R²)ₙSi(OR³)₄₋ₘ₋ₙ (F-1)

wherein R¹ and R² are independently selected as hydrogen or either a substituted or unsubstituted monovalent hydrocarbon group, R³ is a substituted or unsubstituted monovalent hydrocarbon group, and m and n are integers independently selected as 0 or 1 such that m+n is 0, 1 or 2.

When desirable, the atmospheric PECVD film of the outer layer (I) may comprise one or more sub-layers of an organic, organosilicon, organometallic, or metal oxide composition. Optionally, the coating system may further comprise a bottom layer (III) that is located between the inner layer (II) and the substrate. This bottom layer (III) may increase adhesion between the inner layer (II) and the substrate.

According to another aspect of the present disclosure a method of preparing a layered coating system is provided. This method comprises: forming an organic resin substrate; applying an inner layer (II) that at least partially encapsulates a surface of the substrate; at least partially curing the inner layer (II); and applying an atmospheric PECVD film as an outer layer (I) that at least partially encapsulates the inner layer (II). The inner layer (II) and outer layer (I) generally comprise the composition described above and as further defined herein. The outer layer (I) is applied using an atmospheric plasma process that includes an atmospheric plasma jet source and a source gas.

Further areas of applicability will become apparent from the description provided herein. It should be understood that the description and specific examples are intended for purposes of illustration only and are not intended to limit the scope of the present disclosure.

### BRIEF DESCRIPTION OF DRAWINGS

In order that the disclosure may be well understood, there will now be described various forms thereof, given by way of example, reference being made to the accompanying drawings, in which:

FIG. 1A is a schematic representation of a cross-sectional view of a layered coating system formed according to the teachings of the present disclosure;

FIG. 1B is a schematic representation of a cross-sectional view of another layered coating system formed according to the teachings of the present disclosure;

FIG. 2 includes chemical structures associated with Formulas (F-1) to (F-8);

FIG. 3 includes chemical structures associated with Formulas (F-9) to (F-12);

FIG. 4 is a schematic representation of a flowchart that illustrates a method of forming the layered coating system according to the teachings of the present disclosure.

FIG. 5 is a graph of the transmittance exhibited by several coatings prepared according to the present disclosure plotted as a function of the UV-Visible wavelength; and

FIG. 6 is a graph of the percentage transmittance exhibited by several other coatings prepared according to the present disclosure plotted as a function of the UV-Visible wavelength.

The drawings described herein are for illustration purposes only and are not intended to limit the scope of the present disclosure in any way.

### DETAILED DESCRIPTION

The following description is merely exemplary in nature and is in no way intended to limit the present disclosure or its application or uses. For example, the layered coating system made and used according to the teachings contained herein is described throughout the present disclosure in conjunction with automotive components in order to more fully illustrate the composition and the use thereof. The incorporation and use of such a coating system in other applications, such as headlamp covers, aerospace components, motorcycle helmet visors, architectural materials, windows, optical lenses, outdoor signage, appliance components, or lighting components are contemplated to be within the scope of the present disclosure. It should be understood that throughout the description, corresponding reference numerals indicate like or corresponding parts and features.

The present disclosure generally relates to transparent protective coatings for plastic materials used in applications involving long-term outdoor exposure. In other words, the present disclosure describes a coating system that protects plastic articles or components of articles from outdoor exposure, including UV radiation, extreme temperatures, water, acid rain, other fluids and chemicals; scratching and marring from surface contact; and more. The layered coating system and articles formed therewith are characterized by properties that can include UV-absorption, abrasion and scratch resistance, adhesion to the substrate and within the coating layers, haze and visible light transparency, and impact resistance.

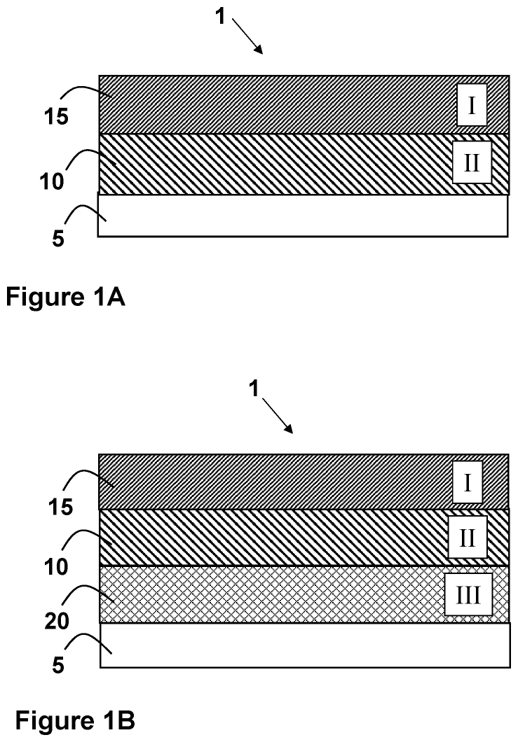

Referring to FIGS. 1A & 1B, a layered coating system 1 is applied to the surface of a plastic substrate 5 in order to enhance durability, as well as resistance to scratches and abrasion under long-term outdoor exposure. The substrate 5 materials can include any type of plastic material that would be used in an application involving long-term outdoor exposure. The coating systems 1 generally are comprised of an inner layer (II) 10 that is siloxane-based and an outer layer (I) 15, which is processed partly or entirely via atmospheric plasma enhanced chemical vapor deposition (PECVD). The siloxane-based hard coating of the inner layer (II) 10 provides weathering protection and resistance to scratch and abrasion. The outer hard layer (I) 15 provides additional weathering protection for longer-term exposure and a high level of scratch and abrasion resistance. The layered coating system 1 may also include, when necessary or desired, an optional bottom layer (III) 20 located between the substrate 5 and inner layer (II) 10 to promote adhesion and further enhance UV protection (see FIG. 1B).

The coating system 1 provides UV protection through the use of organic UV absorbing chemicals or chemical functional groups bonded to the matrix and/or by incorporation of inorganic UV reflecting materials or particles. The coating system 1 also provides enhanced resistance to scratch and abrasion during long-term outdoor exposure (e.g., 10+ years). Furthermore, the methods used to apply the coating system 1 includes processes that are economically feasible and can be easily streamlined for large-scale manufacturing.

Substrate 5

The substrate 5 can be comprised of any polymeric material. In one aspect, the substrate 5 is a transparent plastic substrate comprised of one or more thermoplastic or thermoset resins. Examples of plastic resin materials that may be used to form the substrate 5 include, without limitation, polycarbonate, acrylic, polypropylene, polyethylene, acrylonitrile butadiene styrene, polyvinylacetate, polyamide, polyvinylchloride, polyurethane, polyoxymethylene, polybutylene terephthalate, polystyrene, polymethacrylate ester, polyester, polyether, epoxy, polyvinylalcohol, cellulous resin, polyimide, polysulfone and mixtures or copolymers thereof. The substrates 5 can be formed using any method that is known to one skilled in the art, including but not limited to, injection molding, compression molding, extrusion, blow molding, thermoforming, vacuum forming, cold forming, reaction injection molding, transfer molding, or a combination thereof.

The substrates 5, when desirable, may be surface treated, specifically by conversion treatment, corona discharge treatment, plasma treatment, and/or acid or alkaline treatment. The substrate 5 may also be a laminated substrate, which comprises a bulk substrate made of one resin and a surface layer formed thereon made from a different resin. Several examples, of laminated substrates may include, but not limited to, those comprising, consisting essentially of, or consisting of a polycarbonate resin or a polyester resin substrate and a surface layer of an acrylic resin or an urethane resin. The laminated substrates may be prepared through the use of conventional co-extrusion and/or lamination techniques.

The substrate 5 may further comprise, without limitation, various additives and reinforcement materials, such as colorants, pigments, antioxidants, antistatics, fibers, coupling agents, compatibilizers, plasticizers, lubricants, UV stabilizers, fillers, flame retardants, biocides, conductive additives, and other agents that impart desired functions or properties. The selection of additives incorporated into the substrate is determined based on a variety of factors, including the nature of the polymer material and the intended use of the substrate, to name a few. The substrate 5 may be any shape, thickness, and size that is capable of meeting an identified specification or associated requirements for a predetermined application.

Optional Bottom Layer (III) 20

The bottom layer (III) 20, if used herein, may include, without limitation, an acrylic resin film or a coating layer. For example, the acrylic resin bottom layer (III) may be attached to a polymeric substrate (e.g., polycarbonate, etc.) as a film via any conventional co-extrusion or lamination technique. According to another aspect of the present disclosure, an acrylic resin layer may also be formed on the surface of the formed polymeric substrate (e.g., polycarbonate, etc.) by depositing an acrylic resin primer coating onto said surface followed by subsequent curing or at least partial curing thereof. Several other examples of primer coatings include, but are not limited to, vinyl copolymers having organic UV absorptive groups and alkoxysilyl groups on side chains. The primer coatings may also include those described in JP 4041968, JP-A 2008-120986, and JP-A 2008-274177, the entire contents of which are hereby incorporated by reference.

The bottom layer (III) 20 may comprise an acrylic resin having any known average molecular weight, including but not limited to a molecular weight of about 1,500,000 g/mole or Daltons. Alternatively, the weight average molecular weight of the acrylic resin may be up to about 300,000 g/mole, as measured by GPC versus polystyrene standards.

Since an acrylic resin with poor heat resistance gives rise to problems like scorching during molding, the acrylic resin may have a heat distortion temperature of at least 90° C.; alternatively, at least 95° C.; alternatively, at least 100° C. The upper limit of the heat distortion temperature is not limited, although the upper limit of the heat distortion temperature alternatively may be about 120° C.

Inner Layer (II) 10

According to one aspect of the present disclosure, the inner layer (II) 10 may be a cured silicone film including, but not limited to, a silicone hard coating composition that comprises (II-A) a silicone resin, (II-B) an UV absorbing molecule, and (II-C) a solvent.

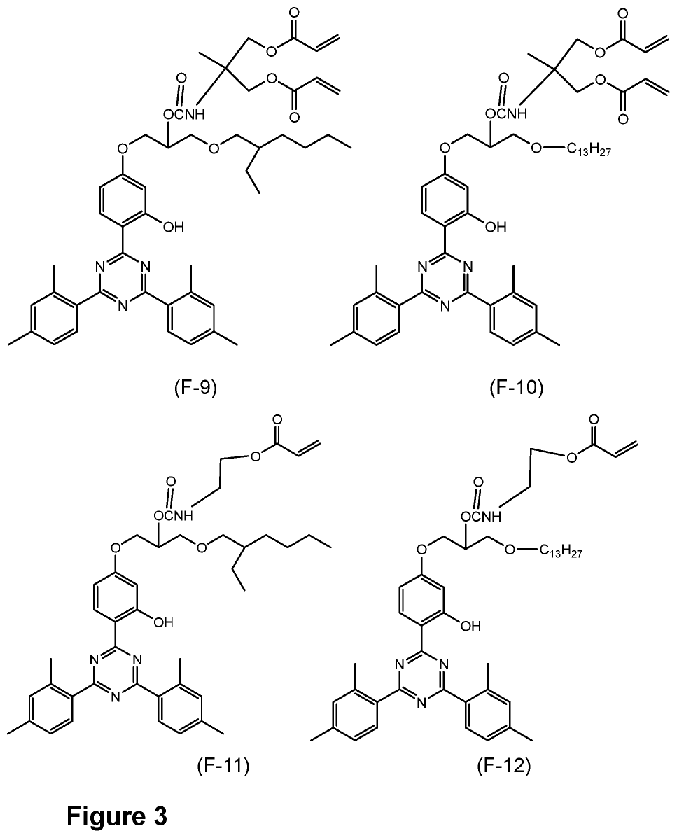

The (II-A) silicone resin present in the silicone coating composition used to form the lower layer (II) 10 may be a reaction product obtained by (co)hydrolyzing, condensing, or (co)hydrolyzing-condensing a member selected from oxysilanes and partial hydrolytic condensates thereof. The oxysilane may correspond to the general Formula (F-1) as shown below and further described in FIG. 3.

(R¹)ₘ(R²)ₙSi(OR³)₄₋ₘ₋ₙ (F-1)

wherein R¹ and R² are independently selected as hydrogen or either a substituted or unsubstituted monovalent hydrocarbon group, R³ is a substituted or unsubstituted monovalent hydrocarbon group, and m and n are independently selected as 0 or 1, such that m+n is 0, 1 or 2. Optionally, the substituted or unsubstituted hydrocarbon groups of R¹ and R² may interact through the formation of one or more bonds there between. In other words, R¹ and R² may be bonded together. In Formula (F-1), the substituted or unsubstituted monovalent hydrocarbon groups of R¹ and R² may comprise from 1 to about 12 carbon atoms; alternatively, between 1 and 8 carbon atoms.

Several specific examples of R¹ and R² include, without limitation hydrogen; alkyl groups, such as methyl, ethyl, propyl, butyl, pentyl, hexyl, heptyl and octyl; cycloalkyl groups, such as cyclopentyl and cyclohexyl; alkenyl groups, such as vinyl and allyl; aryl groups, such as phenyl; halo-substituted hydrocarbon groups, such as chloromethyl, γ-chloropropyl, and 3,3,3-trifluoropropyl; and (meth)acryloxy, epoxy, mercapto, amino or isocyanato-substituted hydrocarbon groups, such as γ-methacryloxypropyl, γ-glycidoxypropyl, 3,4-epoxycyclohexylethyl, γ-mercaptopropyl, γ-aminopropyl, and γ-isocyanatopropyl. An isocyanurate group having a plurality of isocyanato-substituted hydrocarbon groups bonded together represent another example of R¹ and R². Alternatively, alkyl groups may be selected as R¹ and/or R² for use in applications where mar resistance and/or weatherability is required. Epoxy, (meth)acryloxy, and isocyanurate-substituted hydrocarbon groups may be selected for use in applications where toughness, dyeability, and/or another curing system is required.

Similarly, R³ is selected from substituted or unsubstituted monovalent hydrocarbon groups having between 1 to about 12 carbon atoms; alternatively, between 1 and 8 carbon atoms. Several examples of R³ groups include, without limitation, alkyl groups, such as methyl, ethyl, propyl and butyl; cycloalkyl groups, such as cyclopentyl and cyclohexyl; alkenyl groups, such as vinyl and allyl; aryl groups, such as phenyl; halo-substituted hydrocarbon groups, such as chloromethyl, γ-chloropropyl, and 3,3,3-trifluoropropyl; and (meth)acryloxy, epoxy, mercapto, amino, or isocyanato-substituted hydrocarbon groups, such as β-acryloxyethyl, β-methacryloxyethyl, γ-methacryloxypropyl, γ-methacryloxypropyl, γ-glycidoxypropyl, 3,4-epoxycyclo-hexylethyl, γ-mercaptopropyl, γ-aminopropyl, and γ-isocyanatopropyl.

The oxysilane of Formula (F-1), wherein m=0 and n=0 may be (II-A-i) a tetraoxysilane of the Formula: Si(OR³)₄ or a partial hydrolytic condensate thereof. The oxysilane of Formula (F-1) wherein m=1 and n=0 or m=0 and n=1 may be (II-A-ii) a trioxysilane of the Formula: R¹Si(OR³)₃ or R²Si(OR³)₃ or a partial hydrolytic condensate thereof. The oxysilane of Formula (F-1) wherein m=1 and n=1 is (II-A-iii) a dioxysilane of the Formula: (R¹)(R²)Si(OR³)₂ or a partial hydrolytic condensate thereof.

The silicone resin used as component (II-A) may be prepared using the foregoing components (II-A-i), (II-A-ii) and (II-A-iii) in any desired proportion. For the purpose of enhancing storage stability, mar resistance, and crack resistance, the silicone resin used as component (II-A) may comprise between 0 to 50 Si-mol % of component (II-A-i), 50 to 100 Si-mol % of component (II-A-ii) and 0 to 10 Si-mol % of component (II-A-iii), based on the total amount of components (II-A-i), (II-A-ii) and (II-B-iii) which is equal to 100 Si-mol %. Alternatively, the silicone resin used as component (II-A) may comprise 0 to 30 Si-mol % of component (lI-A-i), 70 to 100 Si-mol % of component (II-A-ii) and 0 to 10 Si-mol % of component (II-A-iii).

When component (II-A-ii) of the silicone resin is less than 50 Si-mol %, the silicone resin may have a lower crosslinking density and less curability, tending to form a cured film with a lower hardness. When component (II-A-i) is in excess of 50 Si-mol %, the resin may have a higher crosslinking density and a lower toughness to permit crack formation. For the purpose of this disclosure, Si-mol % is a percentage based on the total silicon (Si) moles, and the Si mole means that in the case of a monomer, its molecular weight is 1 mole, and in the case of a dimer, its average molecular weight divided by 2 is 1 mole.

The silicone resin used as component (II-A) may be prepared through (co)hydrolytic condensation of components (II-A-i), (II-A-ii) and (II-A-iii) by any known method. For example, an oxysilane (II-A-i), (II-A-ii) and (II-A-iii) or partial hydrolytic condensate thereof or a mixture thereof can be (co)hydrolyzed in water at a pH ranging between about 1 to about 7.5, alternatively, the pH is between 2 to 7. At this point, silica nanoparticles dispersed in water, such as silica sol, may be used.

When desirable, a catalyst may be added to the system for adjusting the pH to be within the defined range and to promote hydrolysis. Several examples of catalysts include, but are not limited to, organic acids and inorganic acids, such as hydrogen fluoride, hydrochloric acid, nitric acid, formic acid, acetic acid, propionic acid, oxalic acid, citric acid, maleic acid, benzoic acid, malonic acid, glutaric acid, glycolic acid, methanesulfonic acid, or toluenesulfonic acid; solid acid catalysts, such as cation exchange resins having carboxylic or sulfonic acid groups on the surface; and an acidic water-dispersed silica sol. Alternatively, a silica sol dispersed in water or organic solvent may be co-present upon hydrolysis.

Component (II-B) is an UV absorbing molecule or “absorber”. The UV absorber is not particularly limited as long as components (II-A) and (II-C) are dissolvable or dispersible therein. An organic UV absorber may be used. Several examples of an UV absorber, include without limitation, compound derivatives whose main skeleton is hydroxybenzophenone, hydroxybenzotriazole, cyanoacrylate, or hydroxypenyltriazine.

The UV absorbing molecules may also include polymers, such as vinyl polymers, that have the UV absorber incorporated in a side chain, as well as copolymers thereof formed with another vinyl monomer, and silyl-modified organic UV absorbers, and (partial) hydrolytic condensates thereof. The UV absorbers can include, but not be limited to 2,4-dihydroxybenzophenone, 2,2′,4,4′-tetrahydroxybenzophenone, 2-hydroxy-4-methoxy-benzophenone, 2-hydroxy-4-methoxybenzophenone-5-sulfonic acid, 2-hydroxy-4-n-octoxy-benzophenone, 2-hydroxy-4-n-dodecyloxybenzophenone, 2-hydroxy-4-n-benzyloxybenzo-phenone, 2,2′-dihydroxy-4,4′-dimethoxybenzophenone, 2,2′-dihydroxy-4,4′-diethoxybenzo-phenone, 2,2′-dihydroxy-4,4′-dipropoxybenzophenone, 2,2′-dihydroxy-4,4′-dibutoxybenzo-phenone, 2,2′-dihydroxy-4-methoxy-4′-propoxybenzophenone, 2,2′-dihydroxy-4-meth-oxy-4′-butoxybenzophenone, 2,3,4-trihydroxybenzophenone, 2-(2-hydroxy-5-t-methyl-phenyl)benzotriazole, 2-(2-hy-droxy-5-t-octylphenyl)benzotriazole, 2-(2-hydroxy-3,5-di-t-butylphenyl)benzotriazole, ethyl-2-cyano-3,3-diphenyl acrylate, 2-ethylhexyl-2-cyano-3,3′-diphenyl acrylate, 2-(2-hydroxy-4-hexyloxyphenyl)-4,6-diphenyltriazine, (co)polymers of 2-hydroxy-4-(2-acryloxyethoxy)benzophenone, (co)polymers of 2-(2′-hydroxy-5′-methacryl-oxyethylphenyl)-2H-benzotriazole, the reaction product of 2,4-dihydroxybenzophenone with γ-glycidoxypropyltrimethoxysilane, the reaction product of 2,2′,4,4′-tetra-hydroxybenzophenone with γ-glycidoxypropyltrimethoxysilane, and (partial) hydrolyzates thereof.

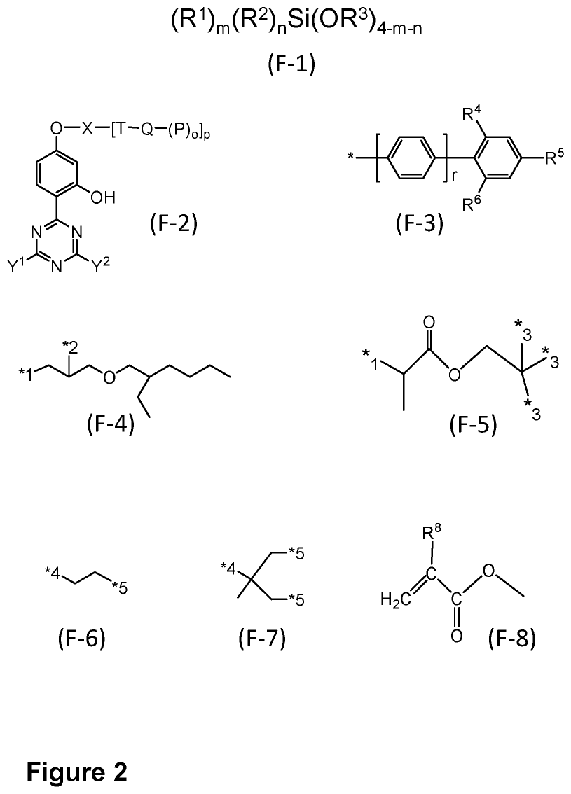

According to one aspect of the present disclosure, a (meta)acrylated hydroxyphenyltriazine may be used as the UV absorber. An example of such a UV absorber is provided according Formula (F-2) as shown below and in FIG. 2.

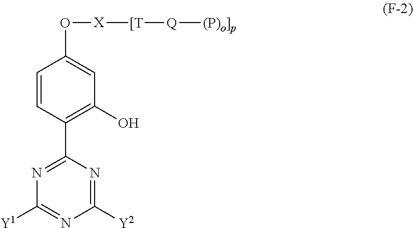

In Formula (F-2), Y¹ and Y² are independently selected to be a substituent group of the general Formula (F-3) shown below and in FIG. 2.

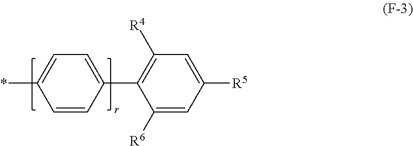

In Formula (F-3), the asterisk (*) stands for a bonding site, and r is an integer of 0 or 1, alternatively, r is 1. Although not wanting to be held to theory, it is believed that in the case of r=1, the radical created upon absorption of ultraviolet (UV) radiation is stabilized because its conjugated system is expanded. R⁴, R⁵ and R⁶ in Formula (F-3) are independently selected to be hydrogen, hydroxyl, C₁-C₂₀ alkyl, C₄-C₁₂ cycloalkyl, C₂-C₂₀ alkenyl, C₁-C₂₀ alkoxy, C₄-C₁₂ cycloalkoxy, C₂-C₂₀ alkenyloxy, C₇-C₂₀ aralkyl, halogen, —C≡N, C₁-C₅haloalkyl, —SO₂R′, —SO₃H, —SO₃M (M=alkali metal), —COOR′, —CONHR′, —CONR′R″, —OCOOR′, —OCOR′, —OCONHR′, (meth)acrylamino, (meth)acryloxy, C₆-C₁₂ aryl (optionally substituted with halogen or the like), or C₃-C₁₂ heteroaryl (optionally substituted with halogen or the like). Alternatively, R⁴, R⁵ and R⁶ may be hydrogen, hydroxyl, C₁-C₂₀ alkyl, C₁-C₂₀ alkoxy, halogen, or C₆-C₁₂ aryl. Alternatively, R⁴, R⁵ and R⁶ are hydrogen or C₁-C₂₀ alkyl. R′ and R″ listed in the Formulas above can each independently be selected as hydrogen, C₁-C₂₀ alkyl, C₄-C₁₂ cycloalkyl, C₆-C₁₂ aryl (optionally substituted with halogen or the like) or C₃-C₁₂ heteroaryl (optionally substituted with halogen or the like). Alternatively, R′ and R″ may be hydrogen, C₁-C₂₀ alkyl, or C₆-C₁₂ aryl. Alternatively, R′ and R″ are selected as either hydrogen or C₁-C₂₀ alkyl.

The X in Formula (F-2) may be a di-, tri- or tetravalent, linear or branched, saturated hydrocarbon residue, such as, for example, C₁-C₂₀ alkyl or C₄-C₁₂ cycloalkyl, which may be separated by at least one element of oxygen, nitrogen, sulfur, and phosphor. For ease of synthesis and availability of starting reactants, X may be, without limitation, a group having the general of Formulas (F-4) or (F-5) as shown below and in FIG. 2.

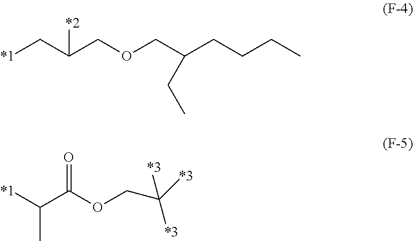

In Formulas (F-4) and (F-5), the *1 bonds to the oxygen in Formula (F-2), *2 bonds to T in Formula (F-2), *3 is independently selected as a hydrogen atom or it bonds to T in Formula (F-2) directly or via a divalent, linear or branched, saturated hydrocarbon group, which may be separated by at least one element of oxygen, nitrogen, sulfur, or phosphorus. Alternatively, at least one *3 bonds to T directly or via a divalent, linear or branched, saturated hydrocarbon group, which may be separated by at least one element of oxygen, nitrogen, sulfur, or phosphorus.

In Formula (F-2), the T is a urethane group —O—(C═O)—NH—, while Q is a di- or trivalent, linear or branched, saturated hydrocarbon residue, such as, for example, C₁-C₂₀ alkyl or C₄-C₁₂ cycloalkyl, which may be separated by at least one element of oxygen, nitrogen, sulfur, or phosphorus. For ease of synthesis and availability of starting reactants, Q may be a group having the general Formula of (F-6) or (F-7) as shown below and in FIG. 2. Herein *4 bonds to T in Formula (F-2), and *5 bonds to P in Formula (F-2).

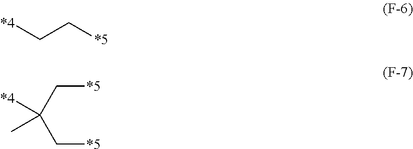

In Formula (F-2), the P is a (meth)acryloxy group, including but not limited to the (meth)acryloxy group shown below and in FIG. 2 having the general Formula (F-8), wherein R⁸ is hydrogen or methyl group. The subscript o in Formula (F-2) is 1 or 2, and p is an integer of 1, 2, or 3. Alternatively, subscript o is 1 or 2 and p is 1.

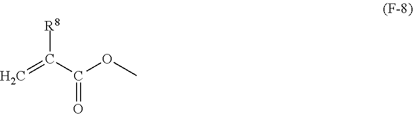

Several specific examples of reactive UV absorbers that are desirable from the aspects of availability of starting reactants and the compatibility with relatively highly polar binder precursors, such as the silicone resin, are shown in Formulas (F-9), (F-10), (F-11), and (F-12) below and in FIG. 3. A reactive UV absorber maintains weather resistance over a long term because the UV absorber is fixed in the layer by reacting with a binder, i.e., the UV absorber is prevented from bleeding out of the inner layer (II). These organic UV absorbers may be used alone or in admixture.

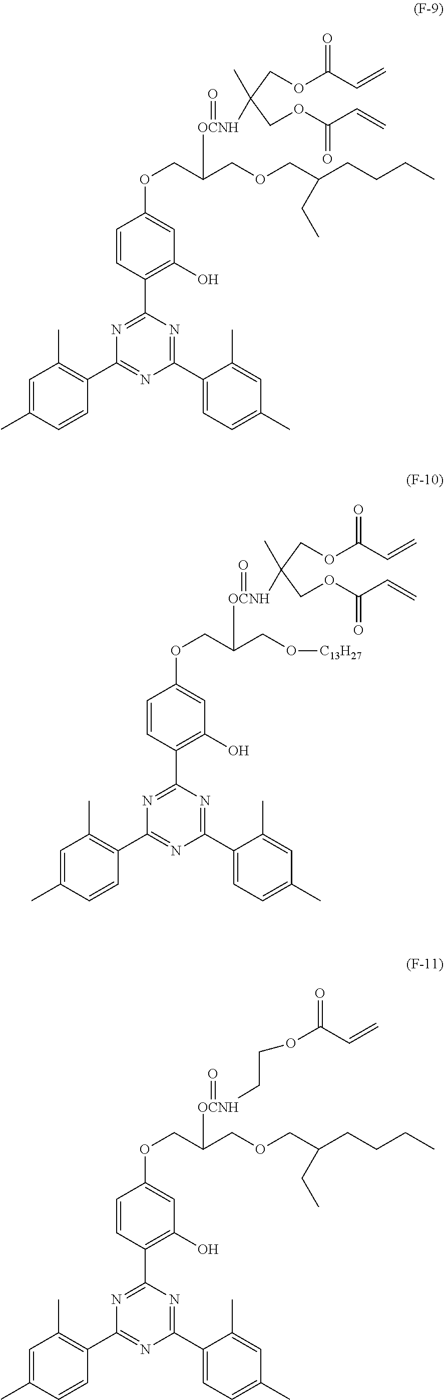

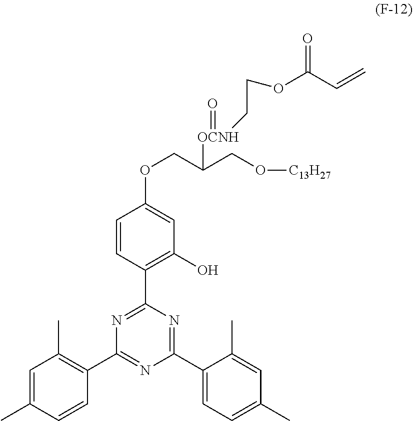

When desirable, an inorganic UV absorber may be used. An example of an inorganic UV absorber, among many examples, is fine metal oxide particles, such as zinc oxide, titanium oxide, cerium oxide, or combinations comprising at least one of the foregoing. From the aspect of transparency of the laminate, the fine metal oxide particles are desirably of nano-size (e.g., less than 1 micrometer). These metal oxide nanoparticles may be added in an appropriate amount when it is desired to increase the hardness and abrasion resistance of the laminate or enhance the UV absorption capability thereof. Such particles have a particle size (or length) of nano- (i.e., nanometer, nm) or submicron order, such as less than 1 micrometer; alternatively, up to 500 nm; alternatively, between about 5 nm to about 200 nm. The nanoparticles may take the form of a dispersion wherein the nanoparticles are dispersed in a medium, such as water or an organic solvent.

According to one aspect of the present disclosure, the inorganic UV absorber comprises, consists of, or consists essentially of fine titanium oxide particles, including but not limited to, a core/shell type tetragonal titanium oxide particle dispersion in which core/shell type tetragonal titanium oxide solid-solution particles comprise a nano-sized core of tetragonal titanium oxide having tin and manganese incorporated in solid solution and a shell of silicon oxide around the core are dispersed in an aqueous dispersing medium. The cores may exhibit a 50% by volume cumulative distribution diameter D₅₀ of up to about 30 nm, and the core/shell type titanium oxide particles may have a 50% by volume cumulative distribution diameter D₅₀ of up to 50 nm, both as measured by a conventional dynamic light scattering method using laser light. The amount of tin incorporated in solid solution provides a molar ratio of titanium to tin (Ti/Sn) in the range of 10/1 to 1000/1. The amount of manganese incorporated in solid solution provides a molar ratio of titanium to manganese (Ti/Mn) of 10/1 to 1000/1. The aqueous dispersing medium may also include an organic solvent. Several examples include, without limitation, ethylene glycol, ethylene glycol/mono-n-propyl ether, ethyl cellosolve, butyl cellosolve, propylene glycol monomethyl ether, propylene glycol monomethyl ether acetate, methyl ethyl ketone, methyl isobutyl ketone, or combinations thereof.

Component (II-C) is a solvent. The solvent is not particularly limited as long as components (II-A) and (II-B) are dissolvable or dispersible therein. According to one aspect of the present disclosure, the solvent may comprise a highly polar organic solvent. Several examples of solvents include, but are not limited to, alcohols, such as methanol, ethanol, isopropyl alcohol, n-butanol, isobutanol, t-butanol, and diacetone alcohol; ketones, such as methyl propyl ketone, diethyl ketone, methyl isobutyl ketone, cyclohexanone, and diacetone alcohol; ethers, such as dipropyl ether, dibutyl ether, anisole, dioxane, ethylene glycol monoethyl ether, ethylene glycol monobutyl ether, propylene glycol monomethyl ether, and propylene glycol monomethyl ether acetate; and esters, such as ethyl acetate, propyl acetate, butyl acetate, and cyclohexyl acetate. The solvents may be used alone or in admixture.

Component (II-C) may be added in such an amount that the silicone coating composition has a solids concentration of about 1 to about 50% by weight; alternatively, about 5 to about 40% by weight. Outside this range, a coating formed upon applying and curing the composition may be defective. A concentration below the range may lead to a coating which is likely to sag, wrinkle or mottle, failing to provide the desired hardness and mar resistance. A concentration beyond the range may lead to a coating which is prone to brushing, whitening, or cracking.

Insofar as a binder is compounded in an effective amount to cure component (II-A) and (II-B), the amount of this binder is not particularly limited. According to one aspect of the present disclosure, this binder may be a multi-functional (meth)acrylate. Examples of other binders, which can be used herein, can be without limitation, multifunctional (meth)acrylates having a polymerizable unsaturated bond, such as, for example, urethane (meth)acrylates, epoxy (meth)acrylates, and polyester (meth)acrylates. The selection of a binder may be made based on the required properties of a coating.

Several, examples of multifunctional (meth)acrylates include but are not limited to, neopentyl glycol di(meth)acrylate, ethylene glycol di(meth)acrylate, polyethylene glycol (n=2-15) di(meth)acrylate, polypropylene glycol (n=2-15) di(meth)acrylate, polybutylene glycol (n=2-15) di(meth)acrylate, 2,2-bis(4-(meth)acryloxyethoxyphenyl)propane, 2,2-bis(4-(meth)acryloxydiethoxyphenyl)propane, trimethylolpropane diacrylate, bis(2-(meth)acryloxy-ethyl)-hydroxyethyl isocyanurate, trimethylol propane tri(meth)acrylate, tris(2-(meth)-acryloxyethyl) isocyanurate, pentaerythritol tri(meth)acrylate, pentaerythritol tetra(meth)-acrylate, dipentaerythritol tetra(meth)acrylate, dipentaerythritol penta(meth)acrylate, dipentaerythritol hexa(meth)acrylate; epoxy poly(meth)acrylates, such as epoxy di(meth)acrylate obtained from reaction of bisphenol A diepoxy with (meth)acrylic acid; urethane poly(meth)acrylates, such as urethane tri(meth)acrylate obtained from reaction of 1,6-hexamethylene diisocyanate trimer with 2-hydroxyethyl (meth)acrylate, urethane di(meth)acrylate obtained from reaction of isophorone diisocyanate with 2-hydroxypropyl (meth)acrylate, urethane hexa(meth)acrylate obtained from reaction of isophorone diisocyanate with pentaerythritol tri(meth)acrylate, urethane di(meth)acrylate obtained from reaction of dicyclohexyl diisocyanate with 2-hydroxyethyl (meth)acrylate, and urethane di(meth)acrylate obtained by reacting the urethanated reaction product of dicyclohexyl diisocyanate and polytetramethylene glycol (n=6-15) with 2-hydroxyethyl (meth)acrylate; and polyester poly(meth)acrylates, such as polyester (meth)acrylate obtained from reaction of trimethylol ethane with succinic acid and (meth)acrylic acid, and polyester (meth)acrylate obtained from reaction of trimethylol propane with succinic acid, ethylene glycol and (meth)acrylic acid. It is noted that “n” used herein designates the number of recurring units in polyethylene glycol and analogues.

The composition of the inner layer (II) can further comprise curing catalyst(s). The curing catalyst promotes condensation reactions of condensable groups such as Si—OH groups in the silicone resin (II-A). Several examples of curing catalysts include, but are not limited to basic compounds, such as lithium hydroxide, sodium hydroxide, potassium hydroxide, sodium methylate, sodium propionate, potassium propionate, sodium acetate, potassium acetate, sodium formate, potassium formate, trimethylbenzylammonium hydroxide, tetramethylammonium hydroxide, tetramethylammonium acetate, n-hexylamine, tributylamine, diazabicycloundecene (DBU), and dicyandiamide; metal-containing compounds, such as tetraisopropyl titanate, tetrabutyl titanate, acetylacetonatotitanium, aluminum triisobutoxide, aluminum triisopropoxide, tris(acetylacetonato)aluminum, aluminum diisopropoxy(ethyl acetoacetate), aluminum perchlorate, aluminum chloride, cobalt octylate, (acetylacetonato)cobalt, (acetylacetonato)iron, (acetylacetonato)tin, dibutyltin octylate, and dibutyltin laurate; and acidic compounds, such as p-toluenesulfonic acid and richloroacetic acid; as well as combinations comprising at least one of the foregoing. Alternatively, these catalysts, may include, without limitation, sodium propionate, sodium acetate, sodium formate, trimethylbenzylammonium hydroxide, tetramethylammonium hydroxide, tris(acetylacetonato)aluminum, and aluminum diisopropoxy(ethyl acetoacetate).

According to one aspect of the present disclosure, the curing catalyst is a photopolymerization initiator that is not particularly limited and may be selected in consideration of compatibility and curability in the photo-curable coating composition. One example, of many examples includes (meta)acrylate compounds.

According to another aspect of the present disclosure, the curing catalysts may include carbonyl compounds, such as benzoin, benzoin monomethyl ether, benzoin isopropyl ether, acetoin, benzyl, benzophenone, p-methoxybenzophenone, diethoxyacetophenone, benzyl dimethyl ketal, 2,2-diethoxyacetophenone, 1-hydroxy-cyclohexyl phenyl ketone, methyl phenyl glyoxylate, and 2-hydroxy-2-methyl-1-phenyl-propan-1-one; sulfur compounds, such as tetramethylthiuram monosulfide and tetramethylthiuram disulfide; phosphoric acid compounds, such as 2,4,6-trimethylbenzoyldiphenylphosphine oxide, 2,4,6-trimethylbenzoylphenylethoxy-phosphine oxide, bis(2,4,6-trimethylbenzoyl)phenylphosphine oxide, and bis(2,6-dimethoxybenzoyl)-2,4,4-trimethylpentylphosphine oxide; 2-benzyl-2-dimethylamino-1-(4-morpholinophenyl)butanone-1 and camphorquinone. These compounds may be used alone or in admixture of two or more. Any two or more of these compounds may be combined in accordance with the required or desired properties of coatings.

The curing catalyst may be used in an amount ranging from 0.0001 wt. % to about 30 wt. %; alternatively, from about 0.001 wt. % to about 10 wt. %, based on the weight of solids of the overall composite coating composition. The use of less than 0.0001 wt. % of the catalyst may lead to under-cure and low hardness. The use of more than 30 wt. % of the catalyst may lead to a coating which is prone to cracking and poorly water resistant.

According to another aspect of the present disclosure, a photostabilizer may be added to the inner layer (II), a photostabilizer having at least one cyclic hindered amine structure or hindered phenol structure in a molecule may be added. The photostabilizer used herein may be low volatile and compatible with the component (II-A), (II-B) and (II-C). Several examples of the photostabilizer used herein include, without limitation, 3-dodecyl-1-(2,2,6,6-tetramethyl-4-piperidinyl)pyrrolidine-2,5-dione, N-acetyl-3-dodecyl-1-(2,2,6,6-tetra-methyl-4-piperidinyl)pyrrolidine-2,5-dione, bis(2,2,6,6-tetra-methyl-4-piperidyl)sebacate, bis(1,2,2,6,6-pentamethyl-4-piperidyl)sebacate, tetrakis-(2,2,6,6-tetramethyl-4-piperidyl) 1,2,3,4-butane-tetracarboxylate, tetrakis(1,2,2,6,6-pentamethyl-4-piperidyl) 1,2,3,4-butane-tetracarboxylate, the condensate of 1,2,3,4-butanetetracarboxylic acid, 2,2,6,6-tetramethyl-4-piperidinol and tridecanol, 8-acetyl-3-dodecyl-7,7,9,9-tetramethyl-1,3,8-triazaspiro[4,5]decane-2,4-dione, the condensate of 1,2,3,4-butanetetracarboxylic acid, 1,2,6,6-pentamethyl-4-piperidinol, and β,β,β,β′-tetramethyl-3,9-(2,4,8,10-tetraoxaspiro[5,5]-undecane)diethanol, and the condensate of 1,2,3,4-butanetetracarboxylic acid, 2,2,6,6-pentamethyl-4-piperidinol and β,β,β,β′-tetramethyl-3,9-(2,4,8,10-tetraoxaspiro[5,5]-undecane)diethanol.

Other useful photostabilizers include those that are modified by silylation for the purpose of anchoring the photostabilizers as described in JP-B S61-56187, the entire content of which is hereby incorporated by reference. Several examples, include but are not limited to 2,2,6,6-tetramethylpiperidino-4-propyltrimethoxysilane, 2,2,6,6-tetramethyl-piperidino-4-propylmethyldimethoxysilane, 2,2,6,6-tetramethylpiperi-dino-4-propyltriethoxy-silane, 2,2,6,6-tetramethylpiperidino-4-propylmethyldiethoxysilane, and (partial) hydrolyzates thereof. These photostabilizers may be used in admixture of two or more.

If desired, one or more additives may be added to the silicone included hard coating composition of which inner layer (II) is formed, insofar as these additives do not adversely affect the properties of the resulting coating. Several examples of such additives include, but are not limited to, pH adjustors, leveling agents, thickeners, pigments, dyes, metal oxide nanoparticles, metal powder, antioxidants, heat reflecting/absorbing agents, plasticizers, antistatic agents, anti-staining agents, and water repellents.

The composite inner layer (II) coating composition may be applied to the substrate by any conventional coating techniques. Several examples of such coating techniques include without limitation, brush coating, spray coating, dipping, flow coating, roll coating, curtain coating, spin coating, and knife coating.

The thickness of the cured inner lower layer (II) is not particularly limited and may be selected as appropriate for a particular application. This cured film generally has a thickness in the range of 0.1 micrometers (μm) to about 50 μm; alternatively, about 3 μm to about 25 μm, e.g., in order to ensure that the cured film has hardness, mar resistance, long-term stable adhesion, and long-term crack resistance.

The inner layer (II) can be overlaid with an outer layer (I) as described above and further defined below. The resulting laminate exhibits a high level of weatherability, e.g., due to the effect of UV absorptive group of component (II-B) in the lower layer (II).

Outer Layer (I)

The outer layer (I) is processed using an atmospheric pressure plasma technique. The type of plasma source may include, but not limited to, corona, dielectric barrier discharge, microwave, atmospheric plasma jets, hollow cathode, and any other source or variation that is known to one skilled in the art. The plasma sources may be powered by a generator that is direct current (DC), pulsed DC, alternating current with any frequency, such as Radio Frequency (RF), or microwave. The source gas for the plasma represents a gas that is capable of generating a plasma discharge from the plasma source. According to one aspect, the source gas for the plasma can include, without limitation, any gas or a combination of gases that do not form a solid film, such as, for example, air, pure nitrogen, helium, argon, oxygen, hydrogen, carbon dioxide, and/or nitrous oxide. Alternatively, the plasma source is comprised of an atmospheric jet formed using a source gas of nitrogen, air, argon, or helium.

According to another aspect of the present disclosure, the outer layer (I) is prepared using Plasma Enhanced Chemical Vapor Deposition (PECVD), in which a vaporized chemical precursor or mixture of precursors reacts with plasma and forms a solid film on the substrate. The precursor(s) may be any compound containing chemical groups that belong to the classes of organic, inorganic, organosilicon, organometallic, metal oxide, or any other class that comprises, consists of, consisting essentially of a molecule capable of undergoing chemical dissociation upon plasma exposure followed by recombination to form a solid film. The precursor or a mixture of precursors can be used as the plasma source gas to generate the plasma or combined with another source gas that does not form a solid film in the plasma generation chamber.

When desirable, the plasma source generation chamber may be decoupled from the location where deposition onto the substrate occurs, such as, for example, in a plasma jet directed to the substrate. In this aspect, the precursor(s) can be injected into the plasma discharge downstream of the plasma source and plasma generation chamber. The precursor(s) may be injected as a liquid or vapor and optionally transported in a stream comprising a carrier gas of nitrogen, argon, oxygen, air, or similar gas or any combination of such gases.

According to yet another aspect of the present disclosure, the precursor(s) are injected into a port that is downstream from the plasma source generation chamber. In this case, the plasma, precursor(s), and products formed from the reaction of the precursor(s) are discharged from a location that is downstream from the injection port and directed towards the substrate. The port may be constructed using any number of inlet ports and in any desired configuration. In one example, the port is comprised of a coaxial nozzle in which the plasma discharges within the inner walls and the precursor(s) are injected into the annular region between the inner and outer walls. The length of the inner chamber of the nozzle can be set to any distance between the plasma source exit where the plasma discharge energy is the highest and the location where the plasma discharge is quenched. The chambers can be any diameter and may have a constant or varying diameter along the axis or length of the nozzle.

The port may be constructed to inject more than one precursor stream into the discharge. For example, the port may comprise injection locations at different distances from the exit of the discharge. In another example, the port may comprise a nozzle with a series of walls and multiple annular regions for injection of multiple precursor streams. Alternatively, the outermost annular region may contain a stream of inert gas, such as nitrogen or argon, as a shield around the deposition process.

According to another aspect of the present disclosure, the outer layer (I) is comprised of multiple sub-layers. The outer layer (I) can be comprised of a single layer or multiple sub-layers prepared by PECVD from any precursor or combination of precursors. The outer-most sub-layer or multiple sub-layers may be prepared from an organic or organosilicon precursor, or a combination thereof. The precursor is not particularly limited, except that it consists of, comprises, or consists essentially of chemical bonds that can undergo dissociation and recombination under plasma exposure to form a solid film on an exposed substrate. Several examples of precursors include, without limitation, any organic, silane, organosilicon, organozinc, organotitanium, organocerium, or other organometallic compound that contains functional groups comprised of carbon, hydrogen, silicon, zinc, titanium, or oxygen, as well as possibly contain other elements, such as nitrogen and/or a metal.

The precursor molecules may contain one or more organic functional groups, including but not limited to, alkyl, vinyl, haloalkyl, hydroxyl, ether, ester, aldehyde, carbonyl, carboxyl, carboxamide, amino, epoxy, acrylate, methacrylate, or phenyl groups. Silanes with Si—C and Si—Si bonds and any organic functional group may be used, such as tetramethyldisilane, hexamethyldisilane, or trimethyl(vinyl)silane.

The precursor may comprise a siloxane, with Si—O—Si linkages, in linear or cyclic form, as well as containing one or more organic functional group. Several examples of suitable linear siloxanes include, without limitation, hexamethyldisiloxane, tetramethyldisiloxane, dimethyldiethoxysilane, octamethyltrisiloxane, decamethyl-tetrasiloxane, or dodecamethylpentasiloxane. Cyclic siloxanes may comprise rings of Si—O—Si linkages. Several examples of cyclic siloxanes, include but are not limited to hexamethylcyclotrisiloxane, octamethylcyclotetrasiloxane, tetramethylcyclotetrasiloxane, decamethylcyclopentasiloxane, or dodecamethylcyclohexasiloxane. Silazane compounds can also be used and are analogous to siloxanes, but with nitrogen, consisting of Si—N—Si linkages in linear or cyclic form. Several examples of silazanes include, without limitation, hexamethyldisilazane, heptamethyldisilazane, tetramethyl-disiazane, diethyltetra-methyldisilazane, hexamethylcyclotrisilazane, octamethylcyclo-tetrasilazane, or tetravinyl-tetramethylcyclotetrasilazane.

When desirable, the precursors may also be an alkoxysilane with one or more Si—O—R linkages, in which R represents any organofunctional group. The molecule can contain 1-4 alkoxy groups attached to a silicon atom and may comprise, consist of, or consist essentially of multipodal alkoxysilanes, in which multiple silicon atoms with alkoxy groups are linked together. The alkoxysilanes may contain any organic functional group, in addition to the alkoxysilane group. Several examples of alkoxysilanes include, without limitation, tetraethoxysilane, methyltriethoxysilane, vinyltriethoxysilane, 3-(acryloxy-propyl)trimethoxysilane, 1,6-bis(trimethoxysilyl)hexane, isocyanatopropyltriethoxysilane, or methacryloxypropyltrimethoxysilane.

In addition, other organometallic compounds may be used as the precursors, such as those that contain zinc, titanium, and cerium. Several examples of such zinc-containing precursors include, but are not limited to, diethyl zinc, zinc 2-ethylhexanoate, zinc undecylenate, zinc acrylate, and zinc methacrylate. Several examples of titanium-containing presursors include, without limitation, titanium n-propoxide, tetrakis(trimethylsiloxy) titanium, titanium ethoxide, titanium isopropoxide, titanium2-ethylhexoxide, and titanium n-butoxide. Several examples of other organometallic compounds include, without limitation, cerium(IV) methoxyethoxide, cerium(III) 2-ethylhexanoate, 3-aminopropyltributylgermane, allyltriethylgermane, di-n-butylgermane, diethyldiethoxygermane, ethyltriethoxygermane, hexaethyldigermoxane, tetraethoxy-germane, tetramethoxygermane, tetramethylgermane, aluminum s-butoxide, aluminum-titanium alkoxides, aluminum-zirconium alkoxides, aluminum magnesium isopropoxide, aluminum di-s-butoxide ethylacetoacetate, antimony(III) n-butoxide, and antimony (III) ethoxide.

The atomic composition of the sub-layers prepared from PECVD of organosilicon precursors may comprise between 10-30% carbon, 20-30% silicon, and 50-70% oxygen. In addition, the total thickness of the outer layer (I) may be between 0.5 and about 5.0 micrometers (μm). Alternatively, the thickness is between about 1.0 and about 3.0 micrometers (μm).

The outer layer (I) may comprise a sub-layer or multiple sub-layers that contain UV protective properties prepared from a UV absorbing or UV reflecting precursor or a combination thereof. The UV protective precursor may contain metals or metal oxides of zinc, titanium, cerium, or a combination thereof. The metal oxides can be in the form of oxide nanoparticles or oxide nanoparticles doped other metals, such as, for example, manganese, and dispersed in a solvent or an organosilicon solution. Alternatively, the precursor contains metals and/or metal oxides from the organometallic chemical classes of organozincs, organotitaniums, organoceriums, or a combination thereof. The precursor may also comprise acids containing metals of titanium, zinc, or cerium.

According to another aspect of the present disclosure, the UV protective precursor may be comprised of an organic molecule or chemical functional group that has UV absorbing properties. Examples of chemical classes of functional groups with UV absorbing properties include, but are not limited to, benzophenones, benzotriazoles, triazines, and cyanoacrylates, as well as others as described previously for the (II) lower layer (II-B) UV absorber. These molecules may also contain chemical functional groups that belong to the chemical classes of organic or organometallic, such as organosilicon, for example.

The UV protective precursor may be incorporated into the plasma process by any number of methods available to one skilled in the art. For example, the UV protective precursor may be injected into the plasma process chamber, plasma source, or a port located downstream from the plasma source as described previously. Alternatively, the UV protective precursor can be applied to the substrate surface by dip coating, flow coating, spray application, or another conventional coating technique, followed by plasma exposure using a source gas that does not form a solid film or followed by PECVD of a sub-layer onto the substrate surface as described previously. The UV protective precursor may also be applied prior to plasma processing or simultaneously by an application process upstream from the plasma process.

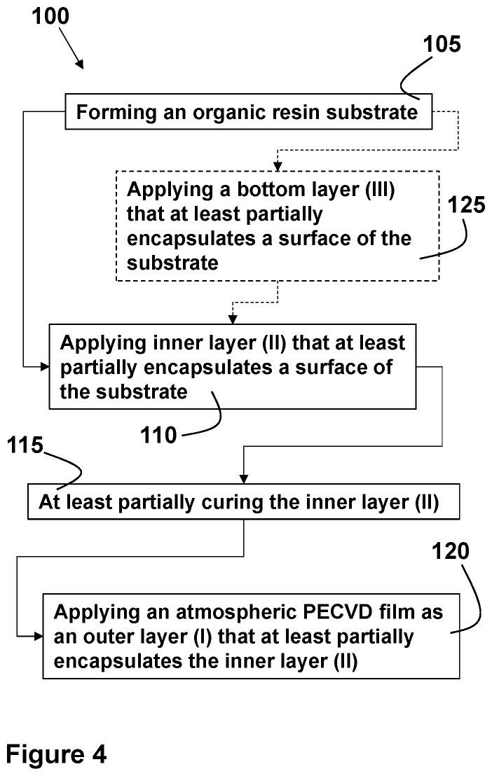

According to another aspect of the present disclosure, a method of forming a layered coating composition on a substrate is provided. Referring now to FIG. 4, the method 100 comprises forming 105 an organic resin substrate; applying 110 an inner layer (II) that at least partially encapsulates a surface of the substrate; at least partially curing 115 the inner layer (II); and applying 120 an atmospheric PECVD film as an outer layer (I) that at least partially encapsulates the inner layer (II). Optionally, a bottom layer (III) can be applied 125 that at least partially encapsulates a surface of the substrate.

The chemical formulations for any layer, the process methods and steps for forming each layer, as well as process conditions can be modified and tailored to achieve desired target properties, such as UV light transmission, scratch resistance, wear resistance, friction, hydrophilicity, hydrophobicity, oleophilicity, oleophobicity, dirt-repellency, chemical resistance, biocompatibility, adhesion, surface energy, refractive index, or some other property.

For the purpose of this disclosure the terms “about” and “substantially” are used herein with respect to measurable values and ranges due to expected variations known to those skilled in the art (e.g., limitations and variability in measurements).

For the purpose of this disclosure, the term “weight” refers to a mass value, such as having the units of grams, kilograms, and the like. Further, the recitations of numerical ranges by endpoints include the endpoints and all numbers within that numerical range. For example, a concentration ranging from 40% by weight to 60% by weight includes concentrations of 40% by weight, 60% by weight, and all concentrations there between (e.g., 40.1%, 41%, 45%, 50%, 52.5%, 55%, 59%, etc.).

For the purpose of this disclosure any range in parameters that is stated herein as being “between [a 1^{st} number] and [a 2^{nd} number]” or “between [a 1^{st} number] to [a 2^{nd} number]” is intended to be inclusive of the recited numbers. In other words the ranges are meant to be interpreted similarly as to a range that is specified as being “from [a 1^{st} number] to [a 2^{nd} number]”.

For the purpose of this disclosure, the terms “at least one” and “one or more of” an element are used interchangeably and may have the same meaning. These terms, which refer to the inclusion of a single element or a plurality of the elements, may also be represented by the suffix “(s)” at the end of the element. For example, “at least one polyurethane”, “one or more polyurethanes”, and “polyurethane(s)” may be used interchangeably and are intended to have the same meaning.

The following specific examples are given to illustrate the weatherable and abrasion resistant coating formed according to the teachings of the present disclosure and should not be construed to limit the scope of the disclosure. Those skilled-in-the-art, in light of the present disclosure, will appreciate that many changes can be made in the specific embodiments which are disclosed herein and still obtain alike or similar result without departing from or exceeding the spirit or scope of the disclosure. One skilled in the art will further understand that any properties reported herein represent properties that are routinely measured and can be obtained by multiple different methods. The methods described herein represent one such method and other methods may be utilized without exceeding the scope of the present disclosure.

Unless otherwise stated in an example, all parts and percentages are by weight. The viscosity of a composition is as measured at 25° C. according to JIS Z8803. The notation, Mw, denotes a weight average molecular weight as determined by gel permeation chromatography (GPC) using polystyrene standards.

### Example 1: Synthesis of Titanium Oxide Dispersion (UV1) for Use as UV Absorber (II-B)

To 66 parts by weight of 36 wt. % titanium(IV) chloride aqueous solution (TC-36, Ishihara Sangyo Kaisha, Ltd., Japan) were added 2.6 parts by weight of tin(IV) chloride pentahydrate (Wako Chemicals USA Inc., Richmond, Va.) and 0.5 part by weight of manganese(II) chloride tetrahydrate (Wako Chemicals USA Inc., Richmond, Va.). The mixture were thoroughly mixed and diluted with 1,000 parts by weight of ion exchanged water. To the metal salt aqueous solution mixture, 300 parts by weight of 5 wt. % aqueous ammonia (Wako Chemicals USA Inc., Richmond, Va.) was gradually added for neutralization and hydrolysis, yielding a precipitate of titanium hydroxide containing tin and manganese. This titanium hydroxide slurry was at a pH of 8. The precipitate of titanium hydroxide was deionized by repeating ion exchanged water addition and decantation.

To the precipitate of titanium hydroxide containing tin and manganese after deionization, 100 parts by weight of 30 wt. % aqueous hydrogen peroxide (Wako Chemicals USA Inc., Richmond, Va.) was gradually added, whereupon stirring was continued at 60° C. for 3 hours for full reaction. Thereafter, pure water was added for concentration adjustment, yielding a brown clear solution of tin and manganese-containing peroxotitanate (solid concentration 1 wt. %). An autoclave of 500 mL volume (TEM-D500 by Taiatsu Techno Co., Ltd., Japan) was charged with 350 mL of the peroxotitanate solution synthesized as above, which was subjected to hydrothermal reaction at 200° C. and 1.5 MPa for 240 minutes.

The reaction mixture in the autoclave was taken out via a sampling tube to a vessel in a water bath at 25° C. whereby the mixture was rapidly cooled to quench the reaction, obtaining a titanium oxide dispersion. The average particle size was measured using a Nanotrac UPA-EX150 (Nikkiso Co., Ltd., Japan) based on the dynamic scattering method using laser light. The average particle size for this titanium oxide dispersion was measured as the 50% cumulative particle size distribution diameter on a volume basis (D₅₀) to be 14 nanometers (nm).

Next, a separable flask equipped with a magnetic stirrer and thermometer was charged with 100 parts by weight of the titanium oxide dispersion, 10 parts by weight of ethanol, and 0.2 parts by weight of ammonia at room temperature, followed by magnetic stirring. The separable flask was placed in an ice bath and cooled until the temperature of the contents reached 5° C. Tetraethoxysilane, 1.8 parts by weight, was added to the separable flask, which was mounted in μReactor EX (Shikoku Instrumentation Co., Inc.) where microwave was applied at a frequency 2.45 GHz and a power 1,000 W for 1 minute while magnetic stirring was continued. The thermometer was monitored during the microwave heating step, confirming that the temperature of the contents reached 85° C. After heating, the reactor was cooled to room temperature in a water bath. The liquid was poured into a round bottom flask and concentrated by batch-wise vacuum distillation. After concentration, the liquid was kept in contact with 10 parts by weight of Amberlite 200CT (Organo Co., Ltd., Japan) for 3 hours. The mixture was filtered using filter paper to remove the ion exchange resin.

The filtrate was a core/shell type titanium oxide solid-solution particle water dispersion (UV1). The dispersion had a solid concentration of 15 wt. %. After the dispersion was diluted to a solid concentration of 1 wt. %, the average particle size (D₅₀) was measured as in the case of titanium oxide dispersion, finding a size D₅₀ of 22.3 nm. In addition, after the dispersion was diluted to a solid concentration of 1 wt,%, UV/visible transmission spectrum was measured to find a transmittance of 90% at 550 nm, indicating the maintenance of satisfactory transparency. Further testing was performed by adding methylene blue (Wako Chemicals USA Inc., special grade, Richmond, Va.) to a 0.5 wt. % core/shell type titanium oxide solid-solution particle water dispersion in a concentration of 0.01 mmol/L, filling a borosilicate glass vial with the dispersion, irradiating black light (UV irradiation intensity 0.5 mW/cm2, as measured by EYE UV illuminometer UVP365-1 of Iwasaki Electric Co., Ltd., Japan) for 24 hours, and colorimetric analysis at 653 nm. The percent decline of absorbance was 5%.

### Example 2: Synthesis of Reactive Hydroxyphenyltriazine (UV2) for Use as UV Absorber (II-B)

A 1-L flask was charged with 87.6 parts by weigh of 2-[4-[(2-hydroxy-3-(2′-ethyl)hexyl)oxy]-2-hydroxyphenyl]-4,6-bis(2,4-dimethylphenyl)-1,3,5-triazine (Tinuvin 405, BASF Corporation, Florham Park, N.J.), 391.5 parts by weigh of propylene glycol monomethyl ether acetate, and 0.12 parts by weigh of methoxyphenol. The mixture was then heated and stirred at 80° C. in a 4% oxygen/nitrogen atmosphere. To the flask, 35.9 parts by weigh of 1,1-bis(acryloyloxymethyl)ethyl isocyanate (Karenz BEI, Showa Denko K.K., Japan) and 0.12 parts by weigh of dioctyltin oxide were added, followed by reaction at 80° C. for 5 hours. The reaction solution was cooled to room temperature, passed through a silica gel-loaded column, and concentrated in vacuum, obtaining 110.8 parts by weight of a yellow clear viscous liquid. The liquid was identified as a reactive hydroxyphenyltriazine of Formula (F-9) as shown in FIG. 3. After the compound was diluted to a solid concentration of 50 wt. % with propylene glycol methyl ether, it was then a reactive hydroxyphenyltriazine solution (UV2) capable of being used as UV absorber (II-B).

### Example 3: Synthesis of Reactive Hydroxyphenyltriazine (UV3) for Use as UV Absorber (II-B)

The procedure of Example 2 was followed except that 87.6 parts by weight of Tinuvin 405 and 21.2 parts by weight of 2-acryloylethyl isocyanate (Karenz AOI, Showa Denko K.K., Japan) were used. The yellow solid that formed was determined to a reactive hydroxyphenyltriazine of Formula (F-11) as shown in FIG. 3. After the compound was diluted to a solid concentration of 50 wt. % with propylene glycol methyl ether, it was then became a reactive hydroxyphenyltriazine solution (UV3) capable of being used as UV absorber (II-B).

### Example 4: Synthesis of Silicone Resin (SR1) for Use as Silicone Resin (II-A)

A total of 142 parts by weight of acryloyloxypropyltrimethoxysilane (KBM-5103, Shin-Etsu Chemical Co., Ltd., Japan) was combined with 500 parts by weight of isopropyl alcohol, 0.1 parts by weight of p-methoxyphenol, 1.0 parts by weight of tetramethylammonium hydroxide, and 20 parts by weight of deionized water. The reaction was allowed to proceed at 20° C. for 24 hours in order to yield a colorless clear liquid. The liquid was concentrated by vacuum distillation and a silicone resin (SR1) was obtained as colorless clear liquid having a nonvolatile content of 99.3% and a Mw of 1,900.

### Example 5: Preparation of Primer Coating Composition for Bottom Layer (III)

A total of 4 parts by weight of acrylic resin (Dianal BR-108, Mitsubishi Rayon Co. Ltd., Japan) and 100 parts by weight of propylene glycol methyl ether were thoroughly mixed at 80° C. for 1 hour. The mixture was cooled to room temperature and then filtered through a nylon mesh strainer, yielding a primer coating for use as bottom layer (III).

### Example 6: Preparation of Silicone Hard Coating Composition (S1) for Inner Layer (II)

A 2-L flask was charged with 136 parts by weight of methyltrimethoxysilane and cooled such that the liquid was at a temperature of about 10° C. A mixture of 100 parts by weight of a water dispersed silica sol (Snowtex O, Nissan Chemical Industries, Ltd., Japan) with an average particle size of 15-20 nm and a SiO₂ content of 20 wt. % and 44.2 parts by weight of a core/shell type titanium oxide solid-solution particle dispersion (UV1) was added to the flask. As the mixture was added, exothermic heat due to hydrolysis was observed, and the internal temperature rose to 50° C. At the end of addition, the contents were stirred at 60° C. for 3 hours to drive the hydrolysis reaction to completion.

Thereafter, 142 parts by weight of cyclohexanone was added to the flask, which was then heated up to a liquid temperature of 92° C. under atmospheric pressure for distilling off the methanol formed by the hydrolysis reaction and for effecting condensation. To the flask were added 189.3 parts by weight of isobutanol as a diluent, 0.1 part by weight of a leveling agent (KP-341, Shin-Etsu Chemical Co., Ltd., Japan), 1.6 parts by weight of acetic acid as a pH adjustor, and 2.5 parts by weight of 10 wt. % tetrabutylammonium hydroxide aqueous solution (Wako Chemicals USA Inc., special grade, Richmond, Va.). Subsequent stirring at room temperature and filtration through a filter paper yielded a silicone resin based hard coating composition (S1) having a nonvolatile concentration of 20.9 wt. %.

### Example 7: Preparation of Silicone Hard Coating Composition (S2) for Use as Inner Layer (II)

The procedure of Example 6 was followed except that the core/shell type titanium oxide solid-solution particle dispersion (UV1) was absent. In this example, a silicone resin based hard coating composition (S2) was obtained.

### Example 8: Preparation of Silicone Hard Coating Composition (S3) for Inner Layer (II)

A 100-mL flask was charged with 136 parts by weight of methyltrimethoxysilane and cooled such that the liquid was at a temperature of about 10° C. A silicone coating composition (S3) was prepared by mixing an UV absorber (II-B), which was compound (UV2) formed in Example 2, with a silicone resin (SR1) as component (II-A), propylene glycol monomethyl ether as component (II-C), and other components at room temperature for 30 minutes, followed by filtering the formed silicone coating composition through a paper filter #2.

### Example 9: PECVD Processing for Forming Outer Layer (1)

Polycarbonate substrates were prepared with inner layer (II) coatings described in the previous examples, some with the bottom layer (III). Atmospheric pressure plasma was used to process the outer layer (I). The atmospheric pressure plasma system was supplied by Plasmatreat North America (PTNA, Ontario, CA) and consists of a pulsed plasma source in which air is used as the plasma gas. Air or nitrogen gas was delivered to the plasma source at a rate of 1,800-2,400 slh (standard liters per hour). A reference percentage for voltage was set at 70-100%, while the output voltage ranged from 235-350 V. The duty ranged from 70-100%.

The precursors tested for PECVD included organosilanes from the following: hexamethyldisiloxane (HMDSO), decamethylcyclopentasiloxane (D5), octamethylcyclo-tetrasiloxane (D4), tetraethylorthosilicate (TEOS), octyltriethoxysilane (OTES), methyltri-ethoxysilane (MTES), vinyltriethoxysilane (VTES), and bis(trimethoxysilyl) hexane. The precursor chemical was delivered to the discharge downstream from the plasma source at a rate between 1.5-60 g/h. Nitrogen at 1-4 L/min was used as a carrier gas for the vaporized precursor.

The precursor injection port and nozzle types tested included a cylindrical single-chamber, in which the precursor was injected into a side port, a double-port nozzle, in which two precursor delivery ports were attached to the nozzle and different axial distances, as well as a co-axial nozzle. Nozzles with precursor injection ports at various distances up to 11.2 mm from the plasma exit were tested. Double port nozzle tests included injection of two different organosilicon precursors through each nozzle, or injection of water or solvent mixture with acetic acid stream in one port and a hydrolyzable organosilicon precursor through the other port. In some cases, different organosilicon precursors were mixed and injected into the plasma as a mixture. For the co-axial nozzle, the plasma discharge was contained in the inner chamber and the precursor was injected in the annular region between the inner and outer walls. The inner chamber length was approximately 15 mm and the outer chamber was approximately 20 mm.

The torch scanned over the stationary substrates in the x- and y-directions using a motor, in which the scan speed was set between 1-30 m/min and distance between scan paths on the substrates was 2-4 mm. The distance between the plasma exit port and the substrate surface was varied between 10-30 mm.

Coatings were prepared over hard coated polycarbonate substrates, silicon wafers, and glass slides. To analyze chemical properties, X-Ray Photoelectron Spectroscopy (XPS) and Fourier Transform Infrared Spectroscopy (FTIR) were used. The chemical functional groups identified from FTIR spectra included Si—O—Si stretching for all samples. For the samples with lower values of the ratio of the plasma input power to the mass flow rate of precursor, peaks representing carbon bonds, including Si—CH₃, Si—C, and CH₂ were present. The XPS data resulted in atomic concentrations for each element as follows: 25-28% Si, 50-65% O, and 10-25% C. The thickness values were measured using a prism coupler (Metricon Corporation, Pennington, N.J.). The thicknesses ranged from less than 1 micrometer to over 5 micrometers.

### Example 10: Plasma Processing for Outer Layer (I) with Sub-Layers Prepared with Nanoparticles and Plasma Exposure

Polycarbonate substrates were prepared with lower layer (II) coatings described in the previous examples, some with the bottom layer (III). Atmospheric pressure plasma was used to process the outer layer (I) and included UV-protective sub-layers. In one case, the sub-layers were prepared from dispersions of metal oxide nanoparticles of zinc oxide and titanium dioxide. The nanoparticles were dispersed in organosilane fluids and diluted with decamethylcyclopentasiloxane to create dispersions with 0.5-10% nanoparticles by mass.

The dispersions of nanoparticles and the chemical precursors were applied to the substrate surface by several methods. One method included injection directly into the plasma glow discharge as a liquid stream into a port at the exit of the plasma torch. Another method included application of the dispersions and chemical precursors onto the substrate by flow or dip coating processes followed by plasma exposure. In other cases, the dispersions were sprayed into the plasma glow discharge and onto the substrate using nitrogen gas as a carrier stream to create an aerosol. In some cases, the plasma was formed using nitrogen, air, and argon without the injection of a precursor. In other cases, the plasma exposure consisted of PECVD deposition of an organosilane precursor injected into a port at the exit of the plasma torch.

An investigation was conducted on glass using air plasma with the spray delivery method to evaluate the effects of nanoparticle type, concentration, plasma energy, air flow rate, pressure of the nitrogen carrier gas, and distance from the plasma jet to the substrate. The solutions consisted of nanoparticles of ZnO (spherical, 20 nm average diameter) and TiO₂ (spindle-shaped, 150 nm average size) in hexamethyldisiloxane (HMDSO) and decamethylcyclopentasiloxane (D5) with mass concentrations of 1.2-2.3%. The solution was delivered through the spray system with a stream of nitrogen as a carrier gas set at pressures of 20-40 psi. The air flow rate was varied at 1800-2400 L/h and the reference voltage was varied at 65-100%. The distance of the substrate to the plasma beam was set to 15-25 mm.

The effects of the nanoparticle concentration and the process parameters on the coating absorbance and transmittance at wavelengths of 300 nm, 340 nm, and 360 nm were evaluated using ANOVA. Based on a p-value less than 0.05, the distance and pressure of the nitrogen carrier gas flow rate for the solution had significant effects for both types of nanoparticles, with the greater distance and lower pressure bringing about greater UV-protection than 15 mm. The reference voltage had a minor effect, with higher settings producing slightly greater UV-protection, possibly due to a higher coating thickness.

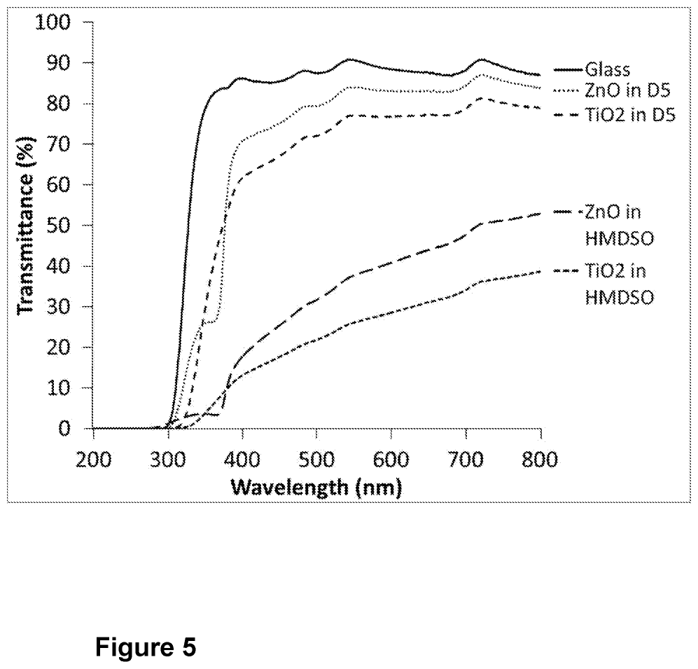

FIG. 5 shows the transmittance of select prepared coatings from 1.8% by weight of nanoparticles in solutions of HMDSO and D5 on glass samples across the UV-visible spectrum. All of the coatings show enhanced UV-protection with lower transmission in the UV range of less than 400 nm. In comparing the types of nanoparticles, TiO₂ has a lower transmittance than ZnO, except for the range of around 350-380 nm. While the TiO₂ coatings provide slightly better protection in the UV-range, it appears hazy compared to the ZnO coatings, which is supported by the higher transmittance of ZnO in the visible range of 400-700 nm.

### Example 11: Plasma Processing for Outer Layer (I) with Sub-Layers Prepared from Organometallic Compounds

UV absorbing sub-layers were prepared on glass slides from organometallic compounds with metals that form UV-blocking oxides. The compounds used in this example were including titanium isopropoxide and titanium ethylhexoxide. A spray apparatus was used to spray the surface of the substrate with the compound immediately prior to plasma exposure with air and nitrogen atmospheric pressure plasma. The reference voltage was varied at 75% and 100% for each gas used.

The coatings prepared with titanium ethylhexoxide appeared clear, while the titanium isopropoxide coatings were white and powdery. The titanium ethylhexoxide coatings showed improved absorbance in the range of 300-350 nm and no change in the visible range from the glass slide. No effect of plasma gas or energy was observed.

Because the titanium isopropoxide produced a powdery coating with the spray method, injection directly into the plasma was evaluated. The precursor was injected into a port on a nozzle attached on the end of the plasma jet where it mixed with the plasma before exiting the nozzle. Nitrogen gas was used and the reference voltage was set at 75%. The coating was clear and the absorbance in the range of 300-350 nm was significantly improved, while the visible range was unchanged.

### Example 12: Plasma Processing for Outer Layer (1) with Sub-Layers Prepared from a Mixture of Organometallic Compounds

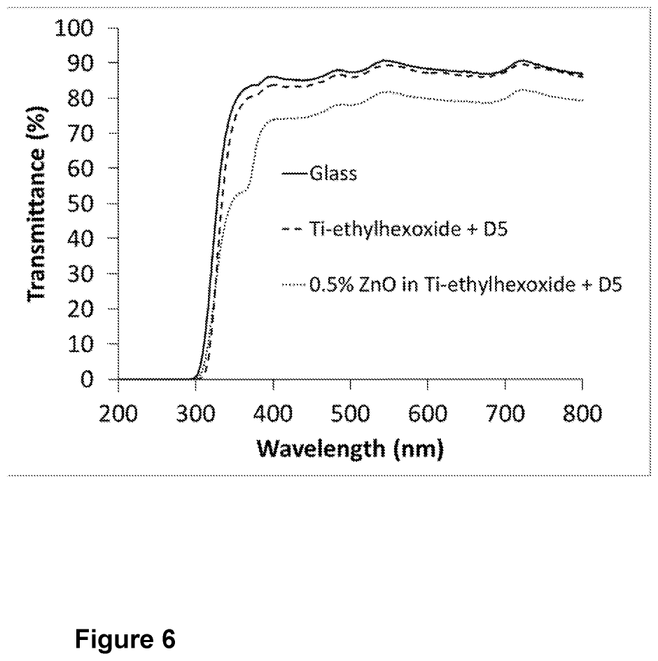

Mixtures of titanium ethylhexoxide and HMDSO or D5 were prepared with a 50/50 mixture by mass. Air plasma was used with ranges of flow rate at 1900-2400 L/h and reference voltage at 75-100%. The mixture was delivered using the continuous spray apparatus and set to coat the surface of the glass slides immediately prior to plasma exposure. All samples showed an improvement in UV-blocking and no effect of the conditions was observed in the range tested. FIG. 6 compares the transmittance of coatings produced from a mixture of titanium ethylhexoxide in D5 to a mixture that contains 0.5% ZnO.

### Example 13: Plasma Processing for Outer Layer (1) Prepared with Injection of Nanoparticle Solution into Plasma

A nozzle was attached to the end of the atmospheric plasma jet to deliver the precursor chemicals. A nozzle with a single port and a double-port nozzle that consisted of two ports lined with the direction of flow were used. For the double-port nozzle, the upstream port delivered HMDSO and the downstream port delivered a UV-blocking solution. The solutions in this example consisted of ZnO and TiO₂ nanoparticles at 0.25-2 wt % in HMDSO or D5. The plasma gas, HMDSO flow rate, solution flow rate, plasma energy, and number of scans were varied to evaluate the effects.

Analysis of the absorbance at 340 nm to evaluate UV-protection and at 550 nm to evaluate the visible clarity was conducted. An increased UV-protection was observed with a higher concentration of nanoparticles, higher mixture flow rate, higher HMDSO flow rate, and greater number of scans. Adhesion was performed using ASTM D3359 in which a grid of 100 squares was cut through the outer layer (II) coatings and tape-pull was conducted according to the test standard. Adhesion was tested after the coatings were prepared and also after placed in boiling water for 2 h. Adhesion passed for all of the preparations onto polycarbonate, except for the solutions with 2% TiO₂ in D5.

### Example 14: Plasma Processing for Outer Layer (1) with Multi-Layer Coatings on Polycarbonate with UV-Blocking Mixtures

Layered coating systems were created onto polycarbonate that was prepared with an inner layer (II) as described in previous examples and some with the bottom layer (III). The coatings consisted of 2-5 UV-blocking layers prepared from a mixture of ZnO nanoparticles (0.5 wt %), titanium ethylhexoxide (1-10 wt %), and D5. Some samples also consisted of three layers prepared with D5 that were coated after the coating of the mixture or alternated with the mixture coatings. The solutions were sprayed using the continuous spray apparatus set to spray the surface immediately prior to plasma exposure. Air plasma was used in the atmospheric plasma jet at a flow rate of 2,000 L/h with the reference voltage set to 80%.

The total thickness of the outer layer coatings was 0.8 micrometer. The presence of the coatings was confirmed with FTIR spectra. The absorbance in the UV-range increased with increasing number of UV-blocking layers and the concentration of titanium ethylhexoxide.

### Example 15: Plasma Processing for Outer Layer (1) with Multi-Layer Coatings on Polycarbonate Including Aqueous UV-Blocking Solutions

Layered coating systems were created with alternating sub-layers prepared by PECVD of methyltriethoxysilane and dip coating of a UV-blocking solution. One such system included a PECVD bottom sub-layer followed by alternating layers of a UV sub-layer and PECVD sub-layer, for a total of four PECVD sub-layers with three dip coated sub-layers. The alternating multi-layer coating systems were tested with separate UV-blocking solutions of Mn-doped titanium dioxide nanoparticles in water and peroxotitanium acid. The solutions were applied by injecting into a port of a nozzle placed at the end of the atmospheric plasma jet, continuous spraying on the substrates prior to plasma exposure, or dipping the substrate into the solution prior to plasma exposure.

The coatings were measured to have thickness values in the range of 1-5 microns. The UV absorbance of the multi-layer coating system was evaluated using UV-vis spectroscopy, which showed the absorbance in the wavelengths of less than 400 nm increased by up to nine times from the baseline uncoated sample.

### Example 16: Multi-Layer Coatings Consisting of PECVD and UV-Blocking Sub-Layers

Multiple sub-layers of PECVD were evaluated on polycarbonate samples with a hard coating prepared with inner layer (I) as well as a bottom layer (III) in some cases. In some cases, sub-layers prepared using UV-blocking solutions were also applied in a variety of configurations and arrangement of the PECVD and UV-blocking sub-layers. The solutions included nanoparticle dispersions in silanes or water, organometallic compounds, aqueous dispersions, and mixtures. These UV-blocking solutions were delivered via spray or injection using a single or double-port nozzle. Plasma processing parameters as well as solution concentrations, flow rates, and plasma processing parameters were varied to evaluate effects.

On some samples, haze testing and Taber abrasion were conducted on according to the test standard ASTM D1044 after 500 cycles. Results from select samples are shown in Table 1.

TABLE 1
Haze and Taber Abrasion Test Results

| Sample | Haze (%) | Taber Delta Haze (%) |
|---|---|---|
| A-1 | 0.8 | 2.5 |
| B-1 | 1.6 | 2.5 |
| C-1 | 0.7 | 3.0 |
| D-1 | 2.1 | 2.7 |
| E-1 | 2.7 | 0.3 |
| F-1 | 1.6 | 2.5 |

Within this specification, embodiments have been described in a way which enables a clear and concise specification to be written, but it is intended and will be appreciated that embodiments may be variously combined or separated without parting from the invention. For example, it will be appreciated that all preferred features described herein are applicable to all aspects of the invention described herein.

The foregoing description of various forms of the invention has been presented for purposes of illustration and description. It is not intended to be exhaustive or to limit the invention to the precise forms disclosed. Numerous modifications or variations are possible in light of the above teachings. The forms discussed were chosen and described to provide the best illustration of the principles of the invention and its practical application to thereby enable one of ordinary skill in the art to utilize the invention in various forms and with various modifications as are suited to the particular use contemplated. All such modifications and variations are within the scope of the invention as determined by the appended claims when interpreted in accordance with the breadth to which they are fairly, legally, and equitably entitled.

1. A weatherable and abrasion resistant coating system, the coating system comprising two or more coating layers that at least partially encapsulate an organic resin substrate; the coating layers including an outer layer (I) formed of an abrasion resistant atmospheric PECVD film, optionally a bottom layer (III), and an inner layer (II) having a cured composition comprising:
(II-A) a silicone resin reaction product obtained by (co)hydrolyzing, condensing, or (co)hydrolyzing-condensing a member selected from oxysilanes and partial hydrolytic condensates thereof, said oxysilane corresponding to Formula (F-1):
(R¹)ₘ(R²)ₙSi(OR³)₄₋ₘ₋ₙ (F-1)
wherein R¹ and R² are independently selected as hydrogen or either a substituted or unsubstituted monovalent hydrocarbon group, R³ is a substituted or unsubstituted monovalent hydrocarbon group, and m and n are integers independently selected as 0 or 1 such that m+n is 0, 1 or 2;
(II-B) an UV absorber, and
(II-C) optionally, a residual amount of a solvent;
wherein, when present, the bottom layer (III) is configured to increase adhesion between the inner layer (II) and the substrate.

2. The layered coating system according to claim 1, wherein R¹ and R² are bonded together.

3. The layered coating system according to claim 1, wherein the UV absorber comprises at least one of a hydroxybenzotriazole derivative, a hydroxyphenyltriazine derivative, titanium dioxide (TiO₂), zinc oxide (ZnO), cerium oxide (CeO₂), or a combination thereof.

4. The layered coating system according to claim 1, wherein the hydroxyphenyltriazine derivative corresponds to Formula (F-2): 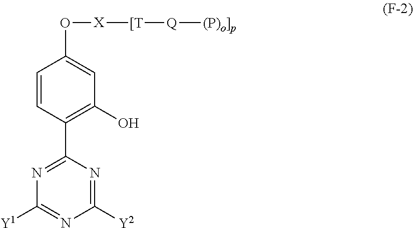
wherein Y¹ and Y² are each independently selected as a substituent group corresponding to the Formula (F-3): 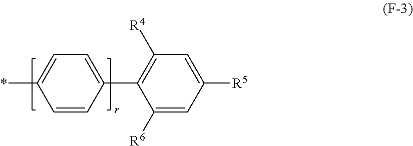
wherein
stands for a bonding site;
r is an integer of 0 or 1;
R⁴, R⁵ and R⁶ are each independently selected from the group consisting of hydrogen, hydroxyl, C₁-C₂₀ alkyl, C₄-C₁₂ cycloalkyl, C₂-C₂₀ alkenyl, C₁-C₂₀ alkoxy, C₄-C₁₂ cycloalkoxy, C₂-C₂₀ alkenyloxy, C₇-C₂₀ aralkyl, halogen, —C≡N, C₁-C₅ haloalkyl, —SO₂R′, —SO₃H, —SO₃M (M=alkali metal), —COOR′, —CONHR′, —CONR′R″, —OCOOR′, —OCOR′, —OCONHR′, (meth)acrylamino, (meth)acryloxy, optionally substituted C₆-C₁₂ aryl or optionally substituted C₃-C₁₂ heteroaryl group, wherein R′ and R″ are each independently selected as a hydrogen, C₁-C₂₀ alkyl, C₄-C₁₂ cycloalkyl, optionally substituted C₆-C₁₂ aryl, or optionally substituted C₃-C₁₂ heteroaryl group;
X is a divalent, trivalent, or tetravalent, linear or branched, saturated hydrocarbon residue, which may or may not be separated by at least one element of oxygen, nitrogen, sulfur, and phosphor;
T is a urethane group —O—(C═O)—NH—;
Q is a divalent or trivalent, linear or branched, saturated hydrocarbon residue, which may or may not be separated by at least one element of oxygen, nitrogen, sulfur, and phosphor,
P is a (meth)acryloxy group;
o is an integer of 1 or 2; and
p is an integer of 1 to 3.

5. The layered coating system of claim 4, wherein R⁴, R⁵ and R⁶ in Formula (F-3) are each independently selected as a hydrogen or a methyl group, X is a group corresponding to Formula (F-4), 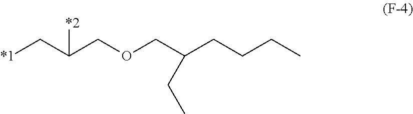
Q is a group according to Formula (F-7), 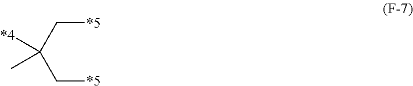
o is 2, and p is 1.

6. The layered coating system according to claim 4, wherein R⁴, R⁵ and R⁶ in Formula (F-3) are each independently selected as a hydrogen or methyl group, X is a group corresponding to Formula (F-4), 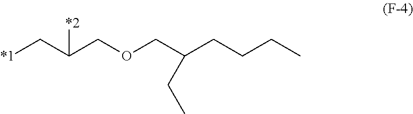
Q is a group according to Formula (F-6), 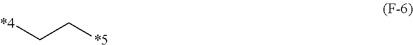
o is 1, and p is 1.

7. The layered coating system according to claim 3, wherein the titanium dioxide (TiO₂) comprises core/shell type tetragonal TiO₂ particles each consisting of a nano-sized core of tetragonal TiO₂ having tin and manganese incorporated in solid solution and a shell of silicon oxide at least partially surrounding the core;
wherein the nano-sized core has a 50% by volume cumulative distribution diameter D₅₀ of up to 30 nm, and the core/shell type TiO₂ particles have a 50% by volume cumulative distribution diameter D₅₀ of up to 50 nm as measured by a dynamic light scattering method using laser light;
wherein the amount of tin incorporated in solid solution provides a molar ratio of titanium to tin (Ti/Sn) of 10/1 to 1000/1, and the amount of manganese incorporated in solid solution provides a molar ratio of titanium to manganese (Ti/Mn) of 10/1 to 1000/1.

8. The layered coating system according to claim 1, wherein the atmospheric PECVD film of outer layer (I) comprises one or more sub-layers of an organic, organosilicon, organometallic, or metal oxide composition having a total thickness that is between about 0.5 and 5.0 micrometers (μm).

9. The layered coating system according to claim 8, wherein at least one sub-layer comprises an organosilicon composition consisting essentially of 10-30% carbon, 20-30% silicon, and 50-70% oxygen.

10. (canceled)

11. The layered coating system according to claim 8, wherein at least one sub-layer of the outer layer (I) comprises one or more organic UV absorbing molecules, organic UV absorbing chemical functional groups, inorganic UV absorbing metal oxide materials, or combinations thereof.

12. (canceled)

13. The layered coating system according to claim 11, wherein the inorganic UV absorbing metal oxide material comprises zinc, titanium, or cerium in the form of oxide nanoparticles optionally doped with manganese or another metal element and homogeneously dispersed within the outer layer (I);
wherein the organic UV absorbing chemical functional groups are selected from the chemical classes of benzophenones, benzotriazoles, triazines, cyanoacrylates, or a mixture thereof.

14. (canceled)

15. (canceled)

16. (canceled)

17. (canceled)

18. (canceled)

19. A method of preparing a layered coating system, the method comprises:
forming an organic resin substrate;
optionally, applying a bottom layer (III) located on a surface of the substrate, wherein the bottom layer (III) increases adhesion between an inner layer (II) and the substrate;
applying the inner layer (II) that at least partially encapsulates a surface of the substrate or the bottom layer (III) when present;
at least partially curing the inner layer (II);
applying an atmospheric PECVD film as an outer layer (I) comprising one or more sublayers that at least partially encapsulates the inner layer (II) using a precursor or mixture of precursors capable of depositing a solid film having an organic, organosilicon, organometallic, or metal oxide composition via an atmospheric plasma process that includes an atmospheric plasma jet source and a source gas that includes compressed air, nitrogen, argon, helium, carbon dioxide, the precursor, or a mixture thereof;
wherein the inner layer (II) comprises:
(II-A) a silicone resin reaction product obtained by (co)hydrolyzing, condensing, or (co)hydrolyzing-condensing a member selected from oxysilanes and partial hydrolytic condensates thereof, said oxysilane corresponding to Formula (F-1):
(R¹)ₘ(R²)ₙSi(OR³)₄₋ₘ₋ₙ (F-1)
wherein R¹ and R² are independently selected as hydrogen or either a substituted or unsubstituted monovalent hydrocarbon group, R³ is a substituted or unsubstituted monovalent hydrocarbon group, and m and n are integers independently selected as 0 or 1 such that m+n is 0, 1 or 2;
(II-B) an UV absorber, and
(II-C) optionally, a residual amount of a solvent.

20. (canceled)

21. (canceled)

22. (canceled)

23. The method according to claim 19, wherein the precursor or mixture of precursors is applied onto a surface of the inner laver (II) prior to exposure of the surface to the atmospheric plasma process or is injected as a vapor, a liquid, or a vapor carried by the source gas in the form of one or more precursor streams through a port at a location downstream from the plasma jet source into a plasma discharge that exits the plasma jet source.

24. The method according to claim 23, wherein the precursor is injected into a coaxial nozzle of constant or varying diameters having inner and outer walls with an annular region located there between,
wherein the plasma discharges through the inner walls and the precursor is injected into the annular region between the inner and outer walls.

25. (canceled)

26. The method according to claim 19, wherein at least one sub-layer of the outer layer (I) is formed by atmospheric plasma processing using one or more UV absorbing precursors.

27. The method according to claim 26, wherein the UV absorbing precursors comprises metal oxide in the form of zinc, titanium, cerium nanoparticles or a combination thereof optionally doped with manganese or another metal element and dispersed in an organic solvent, water, or an organosilicon liquid.

28. (canceled)

29. The method according to claim 26, wherein the UV absorbing precursors are either injected into the atmospheric plasma process through a port located approximate to the plasma source, a plasma chamber, or the plasma discharge that exits the plasma source or the UV absorbing precursors are applied onto a surface of the inner layer (II) using a spray coating, flow coating, dip coating, or similar coating process prior to exposure of the surface to the atmospheric plasma process.

30. (canceled)

31. The method according to claim 19, wherein the organic resin substrate is formed by injection molding, compression molding, extrusion, blow molding, thermoforming, vacuum forming, cold forming, reaction injection molding, transfer molding, or a combination thereof
wherein the inner laver (II) is applied using brush coating, spray coating, dipping, flow coating, roll coating, curtain coating, spin coating, knife coating, or a combination thereof.

32. (canceled)

33. (canceled)

34. An article or a component of an article prepared according to the method of claim 19 that is used as an automotive component, headlamp cover, aerospace component, motorcycle helmet visor, architectural material, window, optical lens, outdoor signage, appliance component, or a lighting component.

35. An article or a component of an article comprising the layered coating system of claim 1 that is used as an automotive component, headlamp cover, aerospace component, motorcycle helmet visor, architectural material, window, optical lens, outdoor signage, appliance component, or a lighting component.

36. (canceled)
